(19) United States
(12) Patent Application Publication
(10) Pub. No.: US 2003/0160257 A1
(43) Pub. Date: Aug. 28, 2003

(54) Radiation-emitting semiconductor component with a vertical emission direction and fabrication method for producing the semiconductor component

(76) Inventors: Stefan Bader, Eilsbrunn (DE); Hans-Jurgen Lugauer, Sinzing (DE); Georg Bruderl, Burglengenfeld (DE); Volker Harle, Laaber (DE)

Correspondence Address: LERNER AND GREENBERG, P.A., POST OFFICE BOX 2480, HOLLYWOOD, FL, 33022-2480, US

(21) Appl. No.: 10/375,764

(22) Filed: Feb. 26, 2003

(30) Foreign Application Priority Data
Feb. 26, 2002 (DE) 102 08 171.9

(51) Int. Cl. H01L 33/00

(52) U.S. Cl. 257/98

(57) ABSTRACT

A radiation-emitting semiconductor component with a vertical emission direction, has a substrate, a first reflector layer, and a semiconductor layer sequence based on InGaN disposed on the first reflection layer. The semiconductor layer sequence contains a radiation-generating active layer. A second reflector layer is disposed on the semiconductor layer sequence and forms, together with the first reflector, a resonator disposed vertically with respect to the main direction of extent of the semiconductor layer sequence and whose axis represents the vertical emission direction of the semiconductor component. The second reflector layer is at least partly transmissive for radiation generated by the active layer and the radiation is coupled out through the second reflector layer. The substrate contains an electrically conductive material. The first reflector layer is a doped, epitaxially grown, distributed Bragg reflector layer, so that a simple electrical contact connection of the semiconductor component is possible without complex construction.

### BACKGROUND OF THE INVENTION

1. Field of the Invention

The present invention relates to a radiation-emitting semiconductor component with a vertical emission direction. The semiconductor component has a substrate, a first reflector layer disposed on the substrate, and a semiconductor layer sequence based on a nitride compound semiconductor, in particular based on InₓGa_{y}N_{1-x-y}, disposed on the first reflection layer. The semiconductor layer sequence contains a radiation-generating active layer. A second reflector layer is disposed on the semiconductor layer sequence, which forms, together with the first reflector, a resonator which is disposed vertically with respect to the main direction of extent of the semiconductor layer sequence and whose axis represents the vertical emission direction of the semiconductor component. The second reflector layer is at least partly transmissive for radiation generated by the active layer and the radiation generated by the active layer is coupled out from the semiconductor component via the second reflector layer. Radiation-emitting semiconductor components such as AlInGaN-based LEDs, for example, whose radiation-generating active layer contains the material system InGaN, exhibit a significant dependence on the wavelength of the emitted radiation on temperature. This effect increases as the In content increases, i.e. for longer wavelengths. The reason for this is because of the temperature-dependent band gap of the radiation-generating layer and, in particular in the case of a high In content, because of fluctuations in the In content. Furthermore, in conventional LEDs, the half-value width of the emission line is determined by the underlying electronic transition, the half-value width of AlInGaN LEDs being relatively wide especially in the case of a high In content, on account of the fluctuations in the In content. Both of the phenomena mentioned lead to problems in applications in which wavelength purity (displays) or wavelength stability (data transmission) is required.

In order to obtain a greater spectral purity of the emitted radiation, the prior art has already disclosed so-called vertical cavity surface emitting lasers (VCSELs) and resonant cavity light emitting diodes (RCLEDs), which have a similar basic structure. Such components usually have on a substrate a first reflector layer, a semiconductor layer sequence with a radiation-generating active layer and a second reflector layer, in this order. In this case, the first reflector layer adjoining the substrate has a reflectivity that is as high as possible, while the second reflector layer serves for the coupling-out of the radiation and therefore has a lower reflectivity. The radiation emission of such a semiconductor component is essentially effected in a vertical emission direction perpendicular to the plane of the active layer or in the axial direction of the resonator formed by the two reflector layers.

VCSELs and RCLEDs having a construction as described above are disclosed in various publications. By way of example, the reference by Y.-K. Song et al., titled “A Vertical Cavity Light-Emitting InGaN Quantum-Well Heterostructure”, Appl. Phys. Lett., Vol. 74, No. 23, Jun. 7, 1999, pages 3441-3443, and their more recent publication titled “Resonant-Cavity InGaN Quantum-Well Blue Light-Emitting Diodes”, Appl. Phys. Lett., Vol. 77, No. 12, Sep. 18, 2000, pages 1744-1746, describe an RCLED structure in which the two reflector layers are formed from a dielectric material. In addition, the layer sequence formed is separated from its sapphire substrate prior to the connection to the electrical contacts, which is difficult, particularly in the case of large-area components.

Furthermore, the reference by N. Nakada et al., titled “Improved Characteristics of InGaN Multiple-Quantum-Well Light-Emitting Diode By GaN/AlGaN Distributed Bragg Reflector Grown on Sapphire”, Appl. Phys. Lett., Vol. 76, No. 14, Apr. 3, 2000, pages 1804-1806, and the reference by T. Someya et al., titled “Room Temperature Lasing at Blue Wavelengths in Gallium Nitride Microcavities”, Science, Vol. 285, Sep. 17, 1999, pages 1905-1906, disclose semiconductor components described in the introduction which are grown on a sapphire substrate and whose reflector layers are formed as nonconductive distributed Bragg reflector layers (DBR, distributed Bragg reflector). On account of the nonconductive substrates and nonconductive DBRs, a relatively high complexity is necessary in the electrical contact connection of these components, as is clearly discernible for example with reference to FIG. 1 of the first-mentioned article.

### SUMMARY OF THE INVENTION

It is accordingly an object of the invention to provide a radiation-emitting semiconductor component with a vertical emission direction and a fabrication method for producing the semiconductor component that overcomes the above-mentioned disadvantages of the prior art devices and methods of this general type, which enables a great spectral purity of the emitted radiation and at the same time a simple electrical contact connection of the semiconductor component.

With the foregoing and other objects in view there is provided, in accordance with the invention, a radiation-emitting semiconductor component having a vertical emission direction. The semiconductor component has a substrate containing an electrically conductive material and a first reflector layer disposed on the substrate. The first reflector layer is a doped, epitaxially grown, distributed Bragg reflector layer. A semiconductor layer sequence based on a nitride compound semiconductor is disposed on the first reflector layer. The semiconductor layer sequence contains a radiation-generating active layer. A second reflector layer is disposed on the semiconductor layer sequence, and forms, together with the first reflector layer, a resonator disposed vertically with respect to a main direction of extent of the semiconductor layer sequence. The resonator has an axis representing the vertical emission direction of the radiation-emitting semiconductor component. The second reflector layer is at least partly transmissive for radiation generated by the radiation-generating active layer and the radiation generated is coupled out from the radiation-emitting semiconductor component through the second reflector layer.

Since, in contrast to the previously known semiconductor components, both the substrate and the first reflector layer on the substrate contain an electrically conductive material, an electrical contact connection of the semiconductor component for a vertical current routing is possible without complexity.

In the case of the invention, the resonator is formed by the two reflector layers in particular in such a way that the dependence of the emission wavelength on temperature is advantageously reduced with respect to a corresponding semiconductor structure without a resonator.

The substrate may contain SiC, for example, and the first reflector layer is a doped, epitaxially grown, distributed Bragg reflector layer based on InAlGaN. By way of example, the first reflector layer has layer pairs made of AlGaN and GaN or made of InAlGaN and InAlGaN with different In or Al concentrations, respectively.

In an advantageous development of the invention, the second reflector layer is likewise a doped, epitaxially grown, distributed Bragg reflector layer. In this case, preferably, the first reflector layer is an n-doped, distributed Bragg reflector layer and the second reflector layer is a p-doped, distributed Bragg reflector layer.

As an alternative, the second reflector layer may also be a metallic reflector layer or a dielectric reflector layer.

Preferably, the reflectivity R₁ of the first reflector layer is between about 70% and about 95%, particularly preferably between about 80% and about 90%. By contrast, the reflectivity R₂ of the second reflector layer is chosen to be lower and is preferably between about 60% and about 80%, particularly preferably between about 65% and 75%.

In an advantageous refinement of the invention, the active layer, for example an InGaN layer, is disposed between a first and a second cladding layer, which may be embodied as a GaN layer, for example.

In accordance with a further feature of the invention, an insulation layer with a radiation coupling-out window is disposed between the semiconductor layer sequence and the second reflector layer. An electrically conductive contact layer is then disposed in the radiation coupling-out window.

In accordance with another feature of the invention, a buffer layer made of an electrically conductive material is disposed between the substrate and the first reflector layer.

Other features which are considered as characteristic for the invention are set forth in the appended claims.

Although the invention is illustrated and described herein as embodied in a radiation-emitting semiconductor component with a vertical emission direction and a fabrication method for producing the semiconductor component, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic sectional view of a layer sequence of a first exemplary embodiment of a radiation-emitting semiconductor component according to the invention;

FIG. 2 is a diagrammatic cross-sectional view of the construction of a second exemplary embodiment of the radiation-emitting semiconductor according to the invention; and

FIG. 3 is a diagrammatic cross-sectional view of the construction of a third exemplary embodiment of the radiation-emitting semiconductor component according to the invention.

### DESCRIPTION OF THE PREFERRED EMBODIMENTS

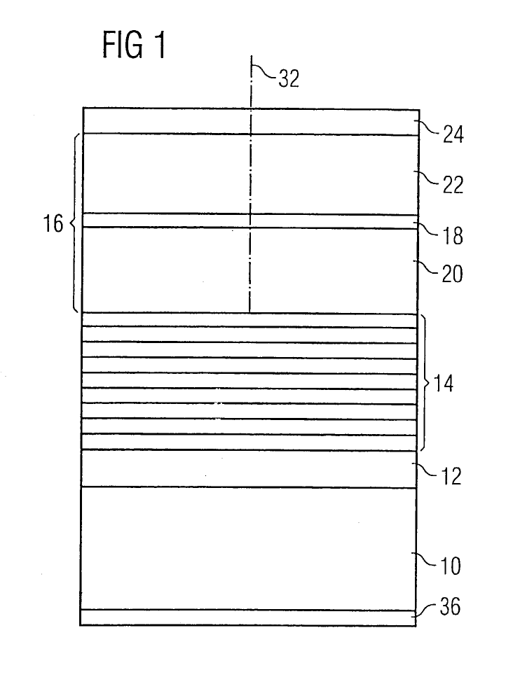

Referring now to the figures of the drawing in detail and first, particularly, to FIG. 1 thereof, there is shown a layer construction of a radiation-emitting semiconductor component with a vertical emission direction in the form of an RCLED in accordance with a first exemplary embodiment of the present invention.

On a substrate 10 made of an electrically conductive material, in particular made of SiC, there is an electrically conductive buffer layer 12 based on GaN or based on AlGaN for connecting the substrate 10 to overlying layers.

An electrically conductive, n-doped, distributed Bragg reflector (DBR) layer 14 based on InAlGaN is subsequently grown epitaxially on the buffer layer 12. In order to obtain a required reflectivity R₁ of about 70% to 95%, preferably about 80% to 90%, a large number of semiconductor layers are necessary in this case in the distributed Bragg reflector layer 14. The first DBR layer 14 preferably has layer pairs made of AlGan and GaN; as an alternative, it is also possible to use layer pairs made in each case of InAlGaN with different In or Al concentrations, respectively. Since the differences in the refractive indices are relatively small with this material selection, the large number—already mentioned—of these layers is necessary.

On account of the high reflectivity R₁ of the first DBR layer 14, the radiation generated in the semiconductor component cannot pass into the substrate 10 and be absorbed there, so that, as mentioned, the electrically conductive substrate 10 made of SiC can be used without difficulty.

On the first reflector layer 14 there is then a semiconductor layer sequence 16 based on InAlGaN, containing an n-conducting lower cladding layer 20 and a p-conducting upper cladding layer 22 between which a radiation-generating active layer 18 is provided. GaN doped with Si, for example, is used for the lower cladding layer 20 and GaN doped with Mg, for example, is used for the upper cladding layer 22. The active layer 18 contains an InGaN layer, for example.

Finally, a second reflector layer 24 is applied to the upper cladding layer 22 of the semiconductor layer sequence 16. The second reflector layer 24 contains an electrically conductive material and is partly transmissive, for the purpose of coupling out radiation, for the radiation to be emitted. The reflectivity R₂ of the second reflector layer 24 is preferably about 60% to 80%, particularly preferably about 65% to 75%. In the exemplary embodiment of FIG. 1, a semitransparent metal layer was chosen as the second reflector layer 24.

The first and second reflector layers 14, 24 together form a resonator which is disposed vertically with respect to the main direction of extent of the semiconductor layer sequence 16 and whose axis 32 at the same time represents the vertical emission direction of the semiconductor component. With the aid of the resonator 14, 24, the wavelength of the radiation emitted by the semiconductor component is set at 435 nm, for example, the half-value width of the emission line of such an RCLED being significantly smaller than in conventional LEDs.

In the exemplary embodiment illustrated in FIG. 1, the second reflector layer 24 made of metal simultaneously serves as an electrode for the electrical contact connection of the semiconductor component. A second electrical connection is effected via a metal layer 36 applied on the underside of the substrate 10, i.e. the side remote from the semiconductor layer sequence 16. Since both the substrate 10 and the first reflector layer 14 are electrically conductive, a simple construction of the electrical connections of the semiconductor component for a vertical current routing is possible in this way without great complexity, in contrast to previously known RCLEDs or VCSELs.

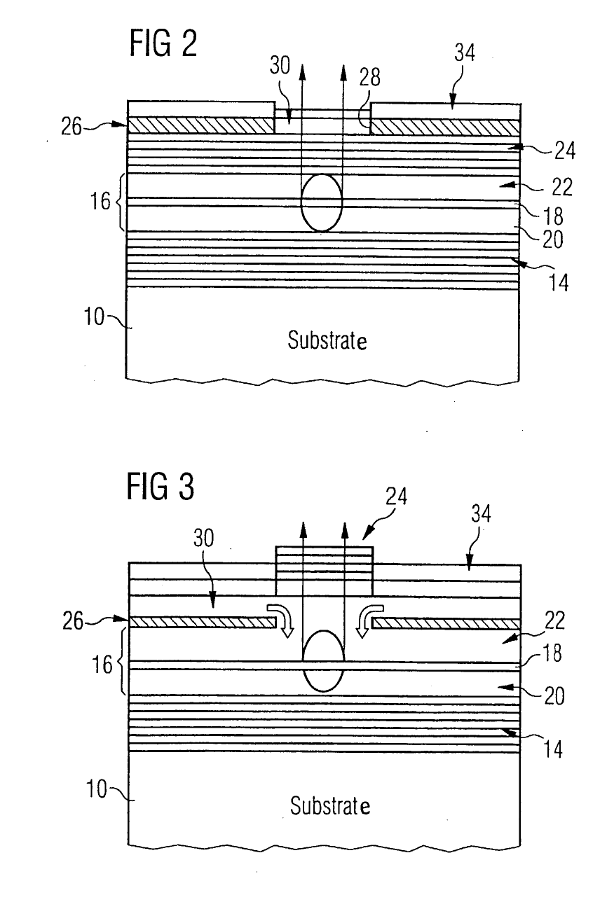

A second exemplary embodiment of the invention is illustrated in FIG. 2. In this case, elements identical to those in FIG. 1 are identified by the same reference numerals. For the sake of clarity, the metal electrode 36 and the buffer layer 12 have been omitted in FIG. 2.

In contrast to the exemplary embodiment of FIG. 1, the RCLED does not have a metal layer applied directly on the semiconductor layer sequence 16 as the second reflector layer 24. Instead, there is grown epitaxially on the upper cladding layer 22 of the semiconductor layer sequence 16 an electrically conductive, p-doped, distributed Bragg reflector (DBR) layer 24, which forms, together with the first, n-doped DBR layer 14, the resonator of the semiconductor component. Once again AlGaN and GaN or alternatively in each case InAlGaN with different In or Al concentrations respectively, can be used as material system for the second DBR layer 24.

An insulator layer 26 with a radiation coupling-out window 28 is applied to the second DBR layer 24. The radiation coupling-out window 28 in the insulator layer 26 is filled with an electrically conductive contact layer 30. A metal layer 34 functioning as a connection electrode is subsequently applied to the insulator layer 26 and the contact layer 30. The insulator layer 26 limits the vertical current direction in the transverse direction and thus also the emission angle of the radiation generated in the active layer 18.

FIG. 3 shows a third alternative embodiment of the radiation-emitting semiconductor component according to the invention. Identical reference numerals again designate the same elements as in the two exemplary embodiments of FIGS. 1 and 2 explained previously. As in FIG. 2, the connection electrode 36 and the buffer layer 12 have been omitted in FIG. 3, too, for the sake of clarity.

In contrast to the two previous exemplary embodiments, in the case of the semiconductor component of FIG. 3, the second reflector layer 24 of the resonator is not provided directly on the semiconductor layer sequence 16 with the active layer 18. In the case of the RCLED illustrated in FIG. 3, first the insulator layer 26 with the radiation coupling-out window 28 is applied to the upper cladding layer 22 of the semiconductor layer sequence 16. The electrically conductive contact layer 30 is then applied to the insulator layer 26 and into the radiation coupling-out window 30.

The second reflector layer 24 in the form of a p-doped DBR, which forms, together with the first DBR layer 14, the resonator of the cavity, is then grown epitaxially on the contact layer 30 above the radiation coupling-out window 28 of the insulator layer. The metal layer 34 as a connection electrode of the semiconductor component is provided around the second DBR layer 24 on the contact layer 30. The vertical current routing is effected via the contact layer, transversely limited by the insulator layer 26.

As an alternative to the p-doped DBR, in the embodiment of FIG. 3, a dielectric reflector layer can also be used as the second reflector layer 24 since the electrical contact connection of the semiconductor component is effected via the metal layer 34.

Both in the second and in the third exemplary embodiment, the reflectivity R₂ of the second reflector layer 24 (DBR or dielectric layer) is preferably about 60% to 80%, particularly preferable about 65% to 75%, so that the layer on the one hand forms the resonator together with the first DBR 14 and, on the other hand, the radiation generated in the active layer 18 can be coupled out from the semiconductor component with a vertical emission direction via the second reflector layer 24.

We claim:

1. A radiation-emitting semiconductor component having a vertical emission direction, comprising:
a substrate containing an electrically conductive material;
a first reflector layer disposed on the substrate, said first reflector layer being a doped, epitaxially grown, distributed Bragg reflector layer;
a semiconductor layer sequence based on a nitride compound semiconductor and disposed on said first reflector layer, said semiconductor layer sequence containing a radiation-generating active layer; and
a second reflector layer disposed on said semiconductor layer sequence, and forms, together with said first reflector layer, a resonator disposed vertically with respect to a main direction of extent of said semiconductor layer sequence, said resonator having an axis representing the vertical emission direction of the radiation -emitting semiconductor component, said second reflector layer being at least partly transmissive for radiation generated by said radiation-generating active layer and the radiation generated being coupled out from the radiation-emitting semiconductor component through said second reflector layer.

2. The semiconductor component according to claim 1, wherein said substrate contains SiC.

3. The semiconductor component according to claim 1, wherein said first reflector layer is based on InAlGaN.

4. The semiconductor component according to claim 1, wherein said second reflector layer is a doped, epitaxially grown, distributed Bragg reflector layer.

5. The semiconductor component according to claim 4, wherein said first reflector layer is an n-doped, distributed Bragg reflector layer and said second reflector layer is a p-doped, distributed Bragg reflector layer.

6. The semiconductor component according to claim 1, wherein said second reflector layer is a metallic reflector layer.

7. The semiconductor component according to claim 1, wherein said second reflector layer is a dielectric reflector layer.

8. The semiconductor component according to claim 1, wherein said first reflector layer has a reflectivity of between about 70% and about 95%.

9. The semiconductor component according to claim 1, wherein said second reflector layer has a reflectivity of between about 60% and about 80%.

10. The semiconductor component according to claim 1, further comprising:
an insulation layer with a radiation coupling-out window formed therein, said insulation layer disposed between said semiconductor layer sequence and said second reflector layer; and
an electrically conductive contact layer disposed in said radiation coupling-out window.

11. The semiconductor component according to claim 1, further comprising a buffer layer made of an electrically conductive material disposed between said substrate and said first reflector layer.

12. The semiconductor component according to claim 1, wherein said nitride compound semiconductor is InₓGa_{y}N_{1-x-y}.

13. A method for fabricating a radiation-emitting semiconductor component with a vertical emission direction, which comprises the steps of:
providing a substrate formed of an electrically conductive material;
growing a first reflector layer on the substrate, the first reflector being a doped, distributed Bragg reflector layer grown epitaxially on the substrate;
applying a semiconductor layer sequence based on InₓGa_{y}N_{1-x-y} to the first reflector layer, the semiconductor layer sequence containing a radiation-generating active layer; and
applying a second reflector layer to the semiconductor layer sequence, the second reflector layer together with the first reflector layer forms a resonator disposed vertically with respect to a main direction of an extent of the semiconductor layer sequence, the resonator having an axis representing the vertical emission direction of the radiation-emitting semiconductor component, the second reflector layer being at least partly transmissive for radiation generated by the radiation-generating active layer and the radiation generated being able to be coupled out from the radiation-emitting semiconductor component through the second reflector layer.

14. The method according to claim 13, which further comprises forming the second reflector layer as a doped, distributed Bragg reflector layer grown epitaxially on the semiconductor layer sequence.

15. The method according to claim 13, which further comprises forming the second reflector layer as a metallic reflector layer.

16. The method according to claim 13, which further comprises forming the second reflector layer as a dielectric reflector layer.

17. The method according to claim 13, which further comprises:
applying an insulation layer having a radiation coupling-out window to the semiconductor layer sequence before the second reflector layer is applied to the semiconductor layer sequence; and
introducing an electrically conductive contact layer into the radiation coupling-out window.

18. The method according to claim 13, which further comprises applying a buffer layer made of an electrically conductive material to the substrate before the first reflector layer grown on the substrate.
